(19) United States
(12) Patent Application Publication
(10) Pub. No.: US 2017/0121564 A1
(43) Pub. Date: May 4, 2017

(54) ADHESIVE FILM, OPTICAL MEMBER INCLUDING THE SAME, AND OPTICAL DISPLAY INCLUDING THE SAME

(71) Applicants: SAMSUNG SDI CO., LTD., Yongin-si (KR); SAMSUNG ELECTRONIC CO., LTD., Suwon-si (KR)

(72) Inventors: Chung Kun CHO, Yongin-si (KR); Mikhail KOVALEV, Suwon-si (KR); Fedosya KALININA, Suwon-si (KR); Hyung Rang MOON, Suwon-si (KR)

(21) Appl. No.: 15/279,930

(22) Filed: Sep. 29, 2016

(30) Foreign Application Priority Data
Oct. 30, 2015 (KR) 10-2015-0152191

(51) Int. Cl. C09J 7/00; H01L 51/00; H01L 51/52

(52) U.S. Cl. CPC C09J 7/00; H01L 51/524; H01L 51/0043; H01L 51/004; C09J 151/003

(57) ABSTRACT

An adhesive film has a glass transition temperature of about −10° C. or less. The adhesive film includes a first region and a second region, the second region being coplanar with the first region. The second region has a higher modulus than the first region at about −20° C. The first region has a modulus of about 0.01 MPa to about 1.5 MPa at about −20° C. The second region has a modulus of about 0.1 MPa to about 50 MPa at about −20° C.

### CROSS-REFERENCE TO RELATED APPLICATION

Korean Patent Application No. 10-2015-0152191, filed on Oct. 30, 2015, in the Korean Intellectual Property Office, and entitled: “Adhesive Film, Optical Member Including the Same, and Optical Display Including the Same,” is incorporated by reference herein in its entirety.

### BACKGROUND

1. Field

Embodiments relate to an adhesive film, an optical member including the same, and an optical display including the same.

2. Description of the Related Art

An optical display includes display members including a window film, a conductive film, an organic light emitting diode, and the like. A touch pad has a stack structure in which a transparent adhesive layer, for example, an optically clear adhesive (OCA) film, is interposed between the window film and the conductive film. The transparent adhesive layer may also be stacked between two of the window film, the conductive film, a polarizing plate, and the organic light emitting diode. Recently, a flexible display has been developed as an optical display.

### SUMMARY

Embodiments are directed to an adhesive film having a glass transition temperature of about −10° C. or less. The adhesive film includes a first region and a second region, the second region being coplanar with the first region. The second region has a higher modulus than the first region at about −20° C. The first region has a modulus of about 0.01 MPa to about 1.5 MPa at about −20° C. The second region has a modulus of about 0.1 MPa to about 50 MPa at about −20° C.

The adhesive film may have a modulus of about 0.05 MPa to about 5 MPa at about −20° C. and a modulus of about 0.01 MPa to about 1 MPa at about 80° C.

The adhesive film may have a peel strength ratio of about 1.1 or more, as calculated by Equation 1:

Peel strength ratio=B/A, [Equation 1]

wherein A is peel strength of the adhesive film at 25° C. and B is peel strength of the adhesive film at 60° C.

The adhesive film may be formed from an adhesive composition including a (meth)acrylic copolymer, a monofunctional (meth)acrylic monomer, a polyfunctional (meth)acrylic monomer, and an initiator.

Each of the monofunctional (meth)acrylic monomer and the polyfunctional (meth)acrylic monomer may have a boiling point of about 200° C. or more.

Each of the monofunctional (meth)acrylic monomer and the polyfunctional (meth)acrylic monomer may be a non-urethane based (meth)acrylic monomer.

The monofunctional (meth)acrylic monomer may include at least one of isobomyl (meth)acrylate, 2-ethylhexyl (meth)acrylate, isooctyl (meth)acrylate, lauryl (meth)acrylate, hydroxypropyl (meth)acrylate, hydroxyethyl (meth)acrylate, stearyl (meth)acrylate, 3-trimethoxysilylpropyl (meth)acrylate, diacetone (meth)acrylamide, (meth)acrylamide, 2-(2-ethoxyethoxy)ethyl (meth)acrylate, 2-methoxyethyl (meth)acrylate, tetrahydrofurfuryl (meth)acrylate, ethylene glycolphenylether(meth)acrylate, isodecyl (meth)acrylate, 2-((meth)acryloyloxy)ethyl succinate, isostearyl(meth)acrylate, caprolactone (meth)acrylate, N,N-dimethyl (meth)acrylamide, octyl (meth)acrylate, octadecyl (meth)acrylate, t-butyl (meth)acrylate, hydroxybutyl (meth)acrylate, dicyclopentadiene (meth)acrylate, and an aromatic acrylate.

The monofunctional (meth)acrylic monomer may be a mixture including a first monofunctional (meth)acrylic monomer, a second monofunctional (meth)acrylic monomer, and a third monofunctional (meth)acrylic monomer in a weight ratio of about 10 to 20:2 to 8:1.

The first monofunctional (meth)acrylic monomer may be or may include at least one of 2-(2-ethoxyethoxy)ethyl (meth)acrylate, 2-ethylhexyl acrylate, isooctyl acrylate, octadecyl acrylate, lauryl acrylate, and t-butyl acrylate. The second monofunctional (meth)acrylic monomer may be or may include at least one of hydroxypropyl (meth)acrylate, hydroxybutyl acrylate, and hydroxyethyl methacrylate. The third monofunctional (meth)acrylic monomer may be or may include at least one of isobornyl (meth)acrylate, dicyclopentadiene (meth)acrylate, and an aromatic acrylate.

The polyfunctional (meth)acrylic monomer may include two to six (meth)acrylate groups.

The monofunctional (meth)acrylic monomer and the polyfunctional (meth)acrylic monomer may be present in a weight ratio of about 1:1 to 5:1.

The (meth)acrylic copolymer may be a copolymer of a hydroxyl group-containing (meth)acrylic monomer and an alkyl group-containing (meth)acrylic monomer.

The (meth)acrylic copolymer may be a copolymer of a hydroxyl group-containing (meth)acrylic monomer, an alkyl group-containing (meth)acrylic monomer, an ethylene glycol unit-containing (meth)acrylate, and a carboxylic acid group-containing monomer.

The adhesive film may have a peel strength at 25° C. of about 500 gf/in or more with respect to a polyethylene terephthalate film subjected to corona treatment.

The adhesive film may have a haze of about 1% or less in the visible region.

The adhesive film may have a total light transmittance of about 90% or more in the visible region.

The adhesive film may have a number of folding cycles of 50,000 or more at about −20° C. and a radius of curvature of about 5 mm or less.

A difference in modulus at about −20° C. between the first region and the second region may be about 0.05 MPa or more.

Embodiments are also directed to an optical member including an optical film and an adhesive film formed on the optical film, wherein the adhesive film is an adhesive film as described above.

Embodiments are also directed to an optical display including the adhesive film as described above.

### BRIEF DESCRIPTION OF THE DRAWINGS

Features will become apparent to those of skill in the art by describing in detail exemplary embodiments with reference to the attached drawings in which:

FIG. 1 illustrates a perspective view of an adhesive film according to an embodiment.

FIGS. 2(a) and 2(b) illustrate conceptual diagrams of a specimen for measuring peel strength.

FIG. 3 illustrates a sectional view of an optical display according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “between” two layers, it can be the only layer between the two layers, or one or more intervening layers may also be present.

Herein, the term “(meth)acryl” refers to acryl and/or methacryl.

Herein, the term “copolymer” may include an oligomer, a polymer, or a resin.

Herein, “peel strength” of an adhesive film refers to T-peel strength thereof. In order to measure peel strength of the adhesive film, a polyethylene terephthalate (PET) film, which has a size of about 150 mm×about 25 mm×about 75 μm (length×width×thickness), is subjected to corona treatment twice (total dose: 156) under corona discharge at a dose of 78 using a corona treatment device, and the corona-treated surfaces of the PET films are laminated onto both surfaces of an adhesive film having a size of about 100 mm×about 25 mm (length×width), followed by aging at 25° C. for 12 hours, thereby preparing a specimen, as shown in FIG. 2(a). Referring to FIG. 2(b), with the specimen secured to a Universal Testing Machine (Instron), the PET film at one side is kept fixed and the PET film at the other side is pulled at 50 mm/min in order to measure T-peel strength. T-peel strength was measured at 25° C. and 60° C.

Herein, “modulus” refers to storage modulus and is measured on a specimen obtained by stacking an adhesive film to a thickness of 600 μm and having a size of 10 mm×10 mm. With the specimens attached to both sides of a middle substrate, viscoelasticity is measured in a shear strain mode under conditions of a frequency of 1 Hz and a strain of 2% (displacement: 16 μM) using a dynamic viscoelasticity instrument DMA (SDTA861, Mettler Co., Ltd.). In the measurement, temperature is increased from −100° C. to 100° C. at a rate of 5° C./min, and modulus is measured at −20° C., 25° C., and 80° C.

Herein, “foldability evaluation” of an adhesive film is carried out on a specimen obtained by sequentially stacking a corona treated PET film (thickness: 75 μm), an adhesive film (thickness: 75 μm) and a corona treated PET film (thickness: 75 μm), followed by aging at 25° C. for 12 hours. In the evaluation of foldability, the specimen is secured to a flexibility evaluation instrument CFT-200 (Covotech Co., Ltd.). Folding is performed at a temperature of −20° C. to 70° C. to a radius of curvature of 5 mm or less, for example, to 3 mm or 5 mm, thirty times per minute while maintaining the specimen in a folded stated for 0.1 seconds after folding the specimen once. In the specimen, the adhesive film is directly formed on the PET film without another adhesive layer or a bonding layer being interposed between the adhesive film and the PET film.

Herein, the “number of folding cycles” of an adhesive film indicates a minimum number of folding cycles at which a striped pattern is initially created at a folded portion of the adhesive film, or at which fracture, slight lifting or peeling of the adhesive film starts to occur in a foldability evaluation (1 cycle refers to an operation of folding the adhesive film in half once and unfolding the adhesive film to its original state). A greater number of folding cycles indicates better foldability and greater suitability for a flexible display.

Herein, “good foldability” refers to 50,000 folding cycles or more in the foldability evaluation without creation of a striped pattern, fracture, slight lifting or peeling of the adhesive film.

The adhesive film according to embodiments may be formed from an adhesive composition that includes a (meth)acrylic copolymer, a monofunctional (meth)acrylic monomer, a polyfunctional (meth)acrylic monomer, and an initiator.

The monofunctional (meth)acrylic monomer and the polyfunctional (meth)acrylic monomer may be cured together with the (meth)acrylic copolymer to form an adhesive film. The monofunctional (meth)acrylic monomer and the polyfunctional (meth)acrylic monomer may provide good foldability to the adhesive film at low temperatures while preventing or reducing the likelihood of failure such as bubble generation at high temperatures, thereby improving reliability of the adhesive film.

The adhesive film may have a modulus at −20° C. of about 0.05 MPa to about 5 MPa, or, for example, about 0.1 MPa to about 3 MPa, and a modulus at 80° C. of about 0.01 MPa to about 1 MPa, or, for example, about 0.02 MPa to about 0.5 MPa. Within this range of modulus, the adhesive film may exhibit good foldability at low temperatures and may not suffer from failure such as bubble generation at high temperatures. The adhesive film may exhibit good foldability even after about 50,000 folding cycles, or, for example, about 50,000 to about 200,000 folding cycles at −20° C. and a radius of curvature of 5 mm or less, for example, at a radius of curvature of 3 mm.

The monofunctional (meth)acrylic monomer and the polyfunctional (meth)acrylic monomer may increase the peel strength of the adhesive film at high temperatures, thereby improving adhesive strength and reliability at high temperatures. With the monofunctional (meth)acrylic monomer and the polyfunctional (meth)acrylic monomer, the adhesive film may have higher peel strength at about 60° C. than at about 25° C., and may have a peel strength ratio of about 1.1 or more, as calculated by the following Equation 1, thereby improving reliability and adhesive strength both at room temperature and at high temperatures. The peel strength ratio of the adhesive film may range from about 1.1 to about 3.

Peel strength ratio=B/A, [Equation 1]

wherein A is peel strength of the adhesive film at 25° C. and B is peel strength of the adhesive film at 60° C.

The adhesive film may have a peel strength at 60° C. of about 200 gf/in or more at a thickness of 50 μm, or, for example, about 200 gf/in to about 5,000 gf/in, with respect to a corona-treated PET film. Within this range, the adhesive film may have good foldability and good reliability both at high temperatures and at low temperatures. The adhesive film may have a peel strength at 25° C. of about 500 gf/in at a thickness of 50 μm, or, for example, about 500 gf/in to about 5,000 gf/in, or, for example, about 700 gf/in to about 2,500 gf/in, or, for example, about 700 gf/in to about 2,000 gf/in, with respect to a corona-treated PET film. Within this range, the adhesive film may exhibit good adhesion and reliability at room temperature.

The adhesive film may have a glass transition temperature of about −10° C. or less, or, for example, about −50° C. to about −20° C., or, for example, about −40° C. to about −25° C. Within this range, the adhesive film may have good bendability at low temperatures and may exhibit good adhesive strength at room temperature and at high temperatures.

The adhesive film may have an index of refraction of about 1.40 to about 1.70, or, for example, about 1.46 to about 1.60. Within this range, the adhesive film may have good matching with optical devices in terms of index of refraction and thus may be used in an optical display.

The adhesive film may have a haze of about 1% or less, or, for example, about 0.1% to about 0.9%, and may have a total light transmittance of about 90% or more, or, for example, about 91% to about 99%, in the visible range (for example, at a wavelength of 380 nm to 780 nm). Within this range, the adhesive film may have good transparency and may be used in an optical display.

The adhesive film may have a thickness of about 10 μm to about 300 μm, or, for example, about 20 μm to about 150 μm. Within this range, the adhesive film may be used in an optical display.

The adhesive film may be formed through irradiation of an adhesive layer that is formed by coating the adhesive composition onto a substrate and drying a solvent, with UV light in a predetermined wavelength range at a same dose. Accordingly, the adhesive film may be composed of a single layer and have the same properties in terms of modulus, peel strength, glass transition temperature, and optical properties on an overall upper surface of the adhesive film. For example, the adhesive film may be formed by irradiating the overall adhesive layer with UV light at an intensity of about 100 mW/cm² to about 1000 mW/cm² and a dose of about 600 mJ/cm² to about 3,000 mJ/cm².

The monofunctional (meth)acrylic monomer and the polyfunctional (meth)acrylic monomer may facilitate modulus adjustment of the adhesive layer through irradiation with UV light at different doses depending upon regions of the adhesive layer, thereby allowing formation of an adhesive film having two or more regions having different moduli even in a single layer structure. For example, with the monofunctional (meth)acrylic monomer and the polyfunctional (meth)acrylic monomer, the adhesive film may be be composed of a single layer that includes a first region and a second region coplanar with the first region and having a higher modulus than the first region.

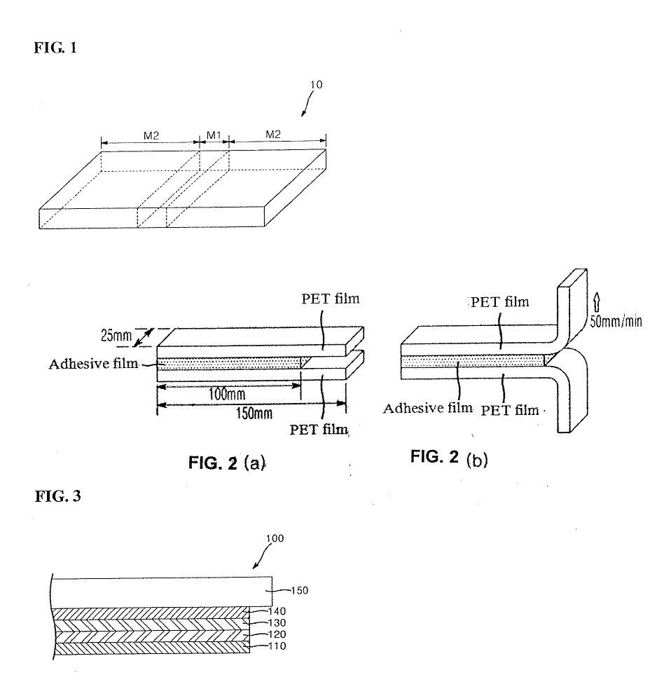

An adhesive film including at least two regions having different moduli will be described with reference to FIG. 1. FIG. 1 illustrates a perspective view of an adhesive film according to an embodiment.

Referring to FIG. 1, an adhesive film 10 may include a first region M1 and a second region M2, which is coplanar with the first region M1 and has a higher modulus than the first region M1. The first region M1 may be formed between the second region M2 and another adjacent second region M2 and may be integrally formed with the second regions M2. Herein, the expression “integrally formed with” indicates that the first region and the second regions are simultaneously formed by coating the same composition once instead of being individually formed and bonded to each other via a bonding agent or adhesives.

The first region M1 may have a modulus at about −20° C. of about 0.01 MPa to about 1.5 MPa, or, for example, about 0.05 MPa to about 1.4 MPa. Within this range, the first region M1 may constitute a bendable region of the adhesive film where a display having the adhesive film applied thereto may be bent, thereby providing good foldability to the display. The second region M2 may have a modulus at about −20° C. of about 0.1 MPa to about 50 MPa, or, for example, about 0.15 MPa to about 5 MPa. Within this range, the second region M2 may constitute a non-bendable region of the adhesive film, where bending is not required, thereby preventing depression of the adhesive film and fracture and/or deformation of a display element, such as an organic light emitting diode or an organic light emitting diode panel, in the non-bendable region.

For example, the first region M1 may have a modulus at about −20° C. of about 0.01 MPa to about 1.5 MPa. A difference in modulus at about −20° C. between the second region M2 and the first region M1 may be adjusted to become about 0.03 MPa or more, or, for example, about 0.05 MPa or more, or, for example, about 0.1 MPa or more, or, for example, about 0.03 MPa to about 2 MPa, or, for example, about 0.06 MPa to about 1.5 MPa, whereby the adhesive film may exhibit good foldability and may maintain the display without deformation in the non-bendable region in which touching operations are carried out. The first region M1 may have a modulus at about 80° C. of about 0.001 MPa to about 1 MPa. A difference in modulus at about 80° C. between the second region M2 and the first region M1 may be adjusted to become about 0 MPa or more, or, for example, about 0 MPa to about 1 MPa, whereby the adhesive film may exhibit good foldability and may maintain the display without deformation in the non-bendable region in which touching operations are carried out.

The adhesive film 10 may have a glass transition temperature of about −10° C. or less, or, for example, about −50° C. to about −20° C., or, for example, about −40° C. to about −25° C. Within this range, the adhesive film may exhibit good bendability at low temperature.

The first region M1 and the second region M2 may have different peel strengths. For example, the first region M1 may have a high peel strength and the second region M2 may have a low peel strength.

The adhesive film 10 may be produced through irradiation of an adhesive layer that is formed by coating the adhesive composition onto a substrate and drying a solvent, using UV light at different doses corresponding to the first region M1 and the second region M2. For example, a portion of the adhesive layer corresponding to the second region M2 may be irradiated with UV light at a higher dose than a portion of the adhesive layer corresponding to the first region M1, thereby forming the first region M1 and the second region M2 on the adhesive film.

In one embodiment, primary UV irradiation may be performed on an overall upper surface of the adhesive layer at an intensity of about 100 mW/cm² to about 1,000 mW/cm² and a dose of about 200 mJ/cm² to about 500 mJ/cm², for example, about 200 mJ/cm² to about 400 mJ/cm², followed by secondary UV irradiation only on a portion of the adhesive layer that will become the second region M2, at an intensity of about 100 mW/cm² to about 1000 mW/cm² and a dose of about 600 mJ/cm² to about 3,000 mJ/cm². A region of the adhesive layer subjected to primary UV irradiation alone will become the first region M1 and a region of the adhesive layer subjected to both primary UV irradiation and secondary UV irradiation will become the second region M2. After primary UV irradiation, secondary UV irradiation may be performed with a mask placed on the portion of the adhesive layer that will become the first region M1, thereby facilitating formation of the first region M1 and the second region M2 while providing a clear boundary therebetween.

In the adhesive film, an area ratio of the first region M1 to the second region M2 may be changed depending upon the kind of display employing the adhesive film.

In the above embodiment, the adhesive film may be composed of a single layer and may include the first region M1 and the second region M2 having different moduli. In some implementations, an adhesive film having at least three regions having different moduli may be formed using the adhesive composition by increasing the number of UV irradiation repetitions. For example, an adhesive film composed of a single layer and including three regions having different moduli may be obtained through primary, secondary and tertiary UV irradiation.

The (meth)acrylic copolymer, the monofunctional (meth)acrylic monomer, the polyfunctional (meth)acrylic monomer, and the initiator will be described in more detail.

The (meth)acrylic copolymer may form a matrix of the adhesive film, may provide adhesive properties of the adhesive film, and may improve bendability of the adhesive film.

The (meth)acrylic copolymer may be a copolymer of a monomer mixture including a hydroxyl group-containing (meth)acrylic monomer and an alkyl group-containing (meth)acrylic monomer.

The hydroxyl group-containing (meth)acrylic monomer may improve adhesion of the adhesive film. The hydroxyl group-containing (meth)acrylic monomer may include at least one of a hydroxyl group-containing (meth)acrylate, a hydroxyl group-containing (meth)acrylamide, and a hydroxyl group and alkylene glycol unit-containing (meth)acrylate. These may be used alone or as a mixture thereof.

The hydroxyl group-containing (meth)acrylate may be a (meth)acrylate containing at least one hydroxyl group. For example, the hydroxyl group-containing (meth)acrylate may include at least one selected from 2-hydroxyethyl (meth)acrylate, 3-hydroxypropyl (meth)acrylate, 4-hydroxybutyl (meth)acrylate, hydroxyhexyl (meth)acrylate, 1,4-cyclohexanedimethanol mono(meth)acrylate, 1-chloro-2-hydroxypropyl (meth)acrylate, diethylene glycol mono(meth)acrylate, 1,6-hexanediol mono(meth)acrylate, pentaerythritol tri(meth)acrylate, dipentaerythritol penta(meth)acrylate, neopentyl glycol mono(meth)acrylate, trimethylolpropane di(meth)acrylate, trimethylolethane di(meth)acrylate, 2-hydroxy-3-phenyloxypropyl (meth)acrylate, 4-hydroxycyclopentyl (meth)acrylate, 4-hydroxycyclohexyl (meth)acrylate, and cyclohexanedimethanol mono(meth)acrylate. These compounds may improve productivity of the adhesive film while further improving the adhesive strength thereof.

The hydroxyl group-containing (meth)acrylamide may include a (meth)acrylamide containing a C₁ to C₁₀ alkyl group having at least one hydroxyl group. For example, the hydroxyl group-containing (meth)acrylamide may include at least one of hydroxyethyl (meth)acrylamide, hydroxypropyl (meth)acrylamide, and hydroxybutyl (meth)acrylamide.

The hydroxyl group and alkylene glycol unit-containing (meth)acrylate may include a monofunctional (meth)acrylate having a hydroxyl group and a plurality of alkylene glycol units at terminal thereof. The alkylene glycol units may be composed of the same kind of alkylene glycol unit or different kinds of alkylene glycol units. The alkylene glycol units may include C₁ to C₅ alkylene glycol units, for example, ethylene glycol and propylene glycol. For example, the hydroxyl group and alkylene glycol unit-containing (meth)acrylate may include at least one of ethylene glycol mono(meth)acrylate having a terminal hydroxyl group and propylene glycol mono(meth)acrylate having a terminal hydroxyl group.

The hydroxyl group-containing (meth)acrylic monomer may be present in an amount of about 4% by weight (wt %) to about 45 wt %, for example, about 4 wt % to about 40 wt %, about 4 wt % to about 35 wt %, or about 4 wt % to about 10 wt %, based on the total weight of the monomer mixture. Within this range, the adhesive film may exhibit further improved adhesive strength and durability/reliability.

The alkyl group-containing (meth)acrylic monomer may serve to form a matrix of the adhesive film. The alkyl group-containing (meth)acrylic monomer may include an unsubstituted C₁ to C₂₀ alkyl group-containing (meth)acrylic ester. For example, the alkyl group-containing (meth)acrylic monomer may include at least one selected from methyl (meth)acrylate, ethyl (meth)acrylate, propyl (meth)acrylate, n-butyl (meth)acrylate, t-butyl (meth)acrylate, i so-butyl (meth)acrylate, pentyl (meth)acrylate, hexyl (meth)acrylate, heptyl (meth)acrylate, ethylhexyl (meth)acrylate, octyl (meth)acrylate, isooctyl (meth)acrylate, nonyl (meth)acrylate, decyl (meth)acrylate, and lauryl (meth)acrylate.

The alkyl group-containing (meth)acrylic monomer may be present in an amount of about 55 wt % to about 96 wt %, for example, about 60 wt % to about 95 wt %, about 70 wt % to about 96 wt %, about 85 wt % to about 95 wt %, or about 90 wt % to about 96 wt %, based on the total weight of the monomer mixture. Within this range, the adhesive film may exhibit further improved adhesive strength and durability/reliability.

In one embodiment, the monomer mixture may include about 4 wt % to about 45 wt % of the hydroxyl group-containing (meth)acrylic monomer, for example, about 4 wt % to about 10 wt %, and about 55 wt % to about 96 wt % of the alkyl group-containing (meth)acrylic monomer, for example, about 90 wt % to about 96 wt %, based on the total weight of the hydroxyl group-containing (meth)acrylic monomer and the alkyl group-containing (meth)acrylic monomer.

The monomer mixture may further include a copolymerizable monomer capable of being copolymerized with the hydroxyl group-containing (meth)acrylic monomer and/or the alkyl group-containing (meth)acrylic monomer. The copolymerizable monomer may be different from the hydroxyl group-containing (meth)acrylic monomer and the alkyl group-containing (meth)acrylic monomer. The copolymerizable monomer may include at least one of an amine group-containing monomer, an amide group-containing monomer, an alkoxy group-containing monomer, a phosphate group-containing monomer, a sulfonate group-containing monomer, a phenyl group-containing monomer, an ethylene glycol unit-containing (meth)acrylate, a propylene glycol unit-containing (meth)acrylate, and an alicyclic group-containing monomer. The copolymerizable monomer may serve to reduce the glass transition temperature of the (meth)acrylic copolymer, to maintain good adhesion of the adhesive film at low temperature (−20° C.), to allow the adhesive film to exhibit similar storage modulus both at high temperature (80° C.) and low temperature (−20° C.), to increase peel strength of the adhesive film at high temperature above peel strength at room temperature, or to increase peel strength of the adhesive film with respect to a hydrophobic adherend not subjected to surface treatment.

The amine group-containing monomer may include amino group-containing (meth)acrylic monomers, such as monomethylaminoethyl (meth)acrylate, monoethylaminoethyl (meth)acrylate, monomethylaminopropyl (meth)acrylate, monoethylaminopropyl (meth)acrylate, dimethylaminoethyl (meth)acrylate, diethylaminoethyl (meth)acrylate, N-tert-butylaminoethyl (meth)acrylate, and methacryloxyethyltrimethyl ammonium chloride (meth)acrylate, as examples.

The amide group-containing monomer may increase the modulus of the adhesive film while suppressing bubble generation at high temperatures. The amide group-containing monomer may include amide group-containing (meth)acrylic monomers such as (meth)acrylamide, N-methyl acrylamide, N-methyl methacrylamide, N-methylol (meth)acrylamide, N-methoxymethyl (meth)acrylamide, or N,N-methylene bis(meth)acrylamide, as examples.

The alkoxy group-containing monomer may include 2-methoxy ethyl (meth)acrylate, 2-methoxypropyl (meth)acrylate, 2-ethoxypropyl (meth)acrylate, 2-butoxypropyl (meth)acrylate, 2-methoxypentyl (meth)acrylate, 2-ethoxypentyl (meth)acrylate, 2-butoxyhexyl (meth)acrylate, 3-methoxypentyl (meth)acrylate, 3-ethoxypentyl (meth)acrylate, or 3-butoxyhexyl (meth)acrylate, as examples.

The phosphate group-containing monomer may include phosphate group-containing acrylic monomers such as 2-methacryloyloxyethyldiphenylphosphate (meth)acrylate, trimethacryloyloxyethylphosphate (meth)acrylate, or triacryloyloxyethylphosphate (meth)acrylate, as examples.

The sulfonate group-containing monomer may include sulfonate group-containing acrylic monomers such as sodium sulfopropyl (meth)acrylate, sodium 2-sulfoethyl (meth)acrylate, or sodium 2-acrylamido-2-methylpropane sulfonate, as examples.

The phenyl group-containing monomer may include phenyl group-containing acrylic vinyl monomers such as p-tert-butylphenyl (meth)acrylate, o-biphenyl (meth)acrylate, or phenoxy ethyl (meth)acrylate, as examples.

The ethylene glycol unit-containing (meth)acrylate may include at least one type of (meth)acrylate containing at least two ethylene glycol units. For example, the ethylene glycol unit-containing (meth)acrylate may include polyethylene oxide alkyl ether (meth)acrylates such as polyethylene glycol monomethyl ether (meth)acrylate, polyethylene glycol monoethyl ether (meth)acrylate, polyethylene glycol monopropyl ether (meth)acrylate, polyethylene glycol monobutyl ether (meth)acrylate, polyethylene glycol monopentyl ether (meth)acrylate, polyethylene glycol dimethyl ether (meth)acrylate, polyethylene glycol diethyl ether (meth)acrylate, polyethylene glycol monoisopropyl ether (meth)acrylate, polyethylene glycol monoisobutyl ether (meth)acrylate, or polyethylene glycol mono-tert-butyl ether(meth)acrylate, as examples.

The propylene glycol unit-containing (meth)acrylate may include polypropylene glycol alkylether (meth)acrylate such as polypropylene glycol monomethyl ether (meth)acrylate, polypropylene glycol monoethyl ether (meth)acrylate, polypropylene glycol monopropyl ether (meth)acrylate, polypropylene glycol monobutyl ether (meth)acrylate, polypropylene glycol monopentyl ether (meth)acrylate, polypropylene glycol dimethyl ether (meth)acrylate, polypropylene glycol diethyl ether (meth)acrylate, polypropylene glycol monoisopropyl ether (meth)acrylate, polypropylene glycol monoisobutyl ether (meth)acrylate, or polypropylene glycol mono-tert-butyl ether (meth)acrylate, as examples.

The alicyclic group-containing monomer may increase the peel strength of the adhesive film with respect to a hydrophobic adherend not subjected to surface treatment. The alicyclic group-containing monomer may be a C₃ to C₂₀ alicyclic group-containing (meth)acrylate and may be or include at least one of isobornyl (meth)acrylate and dicyclopentadiene (meth)acrylate, as examples.

The copolymerizable monomer may be present in an amount of about 10 wt % or less, or, for example, about 7 wt % or less, or, for example, about 0.1 wt % to about 10 wt %. or, for example, about 0.1 wt % to about 5 wt %, based on the total weight of the monomer mixture. Within this range, the adhesive film may exhibit further improved adhesive strength and durability/reliability.

The monomer mixture may further include a carboxylic acid group-containing monomer.

The carboxylic acid group-containing monomer may further increase peel strength of the adhesive film with respect to an adherend.

The carboxylic acid group-containing monomer may include (meth)acrylic acid, 2-carboxyethyl (meth)acrylate, 3-carboxypropyl (meth)acrylate, 4-carboxybutyl (meth)acrylate, itaconic acid, crotonic acid, maleic acid, fumaric acid, or maleic anhydride, as examples. The carboxylic acid group-containing monomer may be present in an amount of about 10 wt % or less, for example, about 0.1 wt % to about 10 wt %, or about 0.1 wt % to about 5 wt %, based on the total weight of the monomer mixture. Within this range, the adhesive film may exhibit further improved adhesive strength and durability/reliability.

In one embodiment, the monomer mixture may include the hydroxyl group-containing (meth)acrylic monomer, the alkyl group-containing (meth)acrylic monomer, the ethylene glycol unit-containing (meth)acrylate, and the carboxylic acid group-containing monomer. With this composition, the adhesive film may easily obtain the ratio of peel strength as calculated by the above Equation 1. For example, the monomer mixture may include about 4 wt % to about 35 wt %, or, for example, about 4 wt % to about 10 wt %, of the hydroxyl group-containing (meth)acrylic monomer, about 60 wt % to about 95 wt %, or, for example, about 85 wt % to about 95 wt %, of the alkyl group-containing (meth)acrylic monomer, about 0.1 wt % to about 10 wt %, or for example, about 0.1 wt % to about 5 wt %. of the ethylene glycol unit-containing (meth)acrylate, and about 0.1 wt % to about 10 wt %, or, for example, about 0.1 wt % to about 5 wt % of the carboxylic acid group-containing monomer, based on the total amount of the hydroxyl group-containing (meth)acrylic monomer, the alkyl group-containing (meth)acrylic monomer, the ethylene glycol unit-containing (meth)acrylate and the carboxylic acid group-containing monomer.

The (meth)acrylic copolymer may have a weight average molecular weight of about 800,000g/mol to about 3,000,000g/mol, or, for example, about 1,000,000g/mol to about 2,500,000g/mol. Within this range, the (meth)acrylic copolymer may increase the coherence of the adhesive film. The weight average molecular weight may be measured by gel permeation chromatography (GPC). For example, the weight average molecular weight may be measured using an Alliance 2690 (Waters Co. Ltd.) for GPC, a PLgel mixed C 2ea column, tetrahydrofuran (THF) as a mobile phase flowing at a flow rate of 1.0 ml/min at an analysis temperature of 40° C., and a refractive index detector (RID).

The (meth)acrylic copolymer may be present in an amount of about 50 parts by weight to about 95 parts by weight, or, for example, about 60 parts by weight to about 90 parts by weight, relative to 100 parts by weight of the (meth)acrylic copolymer, the monofunctional (meth)acrylic monomer and the polyfunctional (meth)acrylic monomer. Within this range, the (meth)acrylic copolymer may contain the (meth)acrylic monomers therein and may be easily handled.

The (meth)acrylic copolymer may be prepared through polymerization of the monomer mixture by a general method. For example, (meth)acrylic copolymer may be prepared by adding an initiator, for example, azobisisobutyronitrile to the monomer mixture, followed by solution polymerization, suspension polymerization, emulsion polymerization, or the like. Polymerization may be performed, for example, at a temperature of about 50° C. to about 200° C. for about 30 minutes to about 10 hours.

The monofunctional (meth)acrylic monomer may be cured together with the polyfunctional (meth)acrylic monomer to provide bendability, good foldability, and high peel strength at high temperature to the adhesive film. The formation of regions having different moduli may be facilitated depending upon the degree of curing of a coating layer.

The monofunctional (meth)acrylic monomer may have a weight average molecular weight of about 80g/mol to about 1,000g/mol. Within this range, the monofunctional (meth)acrylic monomer may improve transparency of the adhesive film by suppressing phase separation upon mixing with the (meth)acrylic copolymer and the polyfunctional (meth)acrylic monomer. The monofunctional (meth)acrylic monomer may be a non-urethane based monomer that is free from (for example, does not include) a urethane group. Thus, the adhesive film may realize advantageous effects for low temperature folding by reducing glass transition temperature and modulus. The monofunctional (meth)acrylic monomer may have a boiling point of about 200° C. or more, or, for example, of about 200° C. to about 400° C. Within this range, the monofunctional (meth)acrylic monomer may be prevented from evaporating from the adhesive composition upon removal of a solvent from the adhesive composition by drying.

The monofunctional (meth)acrylic monomer may include isobornyl (meth)acrylate, 2-ethylhexyl (meth)acrylate, isooctyl (meth)acrylate, lauryl (meth)acrylate, hydroxypropyl (meth)acrylate, hydroxyethyl (meth)acrylate, stearyl (meth)acrylate, 3-trimethoxysilylpropyl (meth)acrylate, diacetone (meth)acrylamide, (meth)acrylamide, 2-(2-ethoxyethoxy)ethyl (meth)acrylate, 2-methoxyethyl (meth)acrylate, tetrahydrofurfuryl (meth)acrylate, ethylene glycol phenyl ether (meth)acrylate, isodecyl (meth)acrylate, 2-((meth)acryloyloxy)ethyl succinate, isostearyl(meth)acrylate, caprolactone (meth)acrylate, N,N-dimethyl (meth)acrylamide, octyl (meth)acrylate, octadecyl (meth)acrylate, t-butyl (meth)acrylate, hydroxybutyl (meth)acrylate, dicyclopentadiene (meth)acrylate, cyclohexyl methacrylate, or an aromatic (meth)acrylate, as examples.

The aromatic (meth)acrylate may be represented by Formula 1:

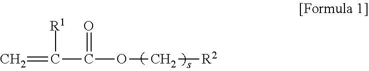

wherein R¹ is hydrogen or a methyl group; s is an integer of 0 to 10; R² is a substituted or unsubstituted C₆ to C₅₀ aryl group or a substituted or unsubstituted C₆ to C₅₀ aryloxy group.

Herein, “substituted” in “substituted or unsubstituted” indicates that at least one hydrogen atom is substituted with a C₁ to C₁₀ alkyl group, a C₁ to C₁₀ thioalkyl group, a C₁ to C₁₀ alkoxy group, a halogen atom (F, Cl, Br or I), a C₃ to C₁₀ cycloalkyl group, or a C₆ to C₂₀ aryl group.

For example, K² may be a substituted or unsubstituted phenoxy group, benzyl group, phenyl group, biphenyl group, terphenyl group, phenyl(phenyl) group. For example, the aromatic (meth)acrylate may include at least one selected from the group of phenoxy methacrylate, 2-ethylphenoxy methacrylate, benzyl methacrylate, phenyl methacrylate, 2-ethylthiophenyl methacrylate, 2-phenylethyl methacrylate, 3-phenylpropyl methacrylate, 4-phenylbutyl methacrylate, 2-(2-methylphenyl)ethyl methacrylate, 2-(3-methylphenyl)ethyl methacrylate, 2-(4-methylphenyl)ethyl methacrylate, 2-(4-propylphenyl)ethyl methacrylate, 2-(4-(1-methylethyl)phenyl)ethyl methacrylate, 2-(4-methoxyphenyl)ethyl methacrylate, 2-(4-cyclohexylphenyl)ethyl methacrylate, 2-(2-chlorophenyl)ethyl methacrylate, 2-(3-chlorophenyl)ethyl methacrylate, 2-(4-chlorophenyl)ethyl methacrylate, 2-(4-bromophenyl)ethyl methacrylate, 2-(3-phenylphenyl)ethyl methacrylate, o-biphenyl methacrylate, m-biphenyl methacrylate, p-biphenyl methacrylate, 2,6-terphenyl methacrylate, o-terphenyl methacrylate, m-terphenyl methacrylate, p-terphenyl methacrylate, 4-(4-methylphenyl)phenyl methacrylate, 4-(2-methylphenyl)phenyl methacrylate, 2-(4-methylphenyl)phenyl methacrylate, 2-(2-methylphenyl)phenyl methacrylate, 4-(4-ethylphenyl)phenyl methacrylate, 4-(2-ethylphenyl)phenyl methacrylate, 2-(4-ethylphenyl)phenyl methacrylate, 2-(2-ethylphenyl)phenyl methacrylate, and mixtures thereof.

The monofunctional (meth)acrylic monomer may be a mixture of a first monofunctional (meth)acrylic monomer, a second monofunctional (meth)acrylic monomer, and a third monofunctional (meth)acrylic monomer. The first monofunctional (meth)acrylic monomer, the second monofunctional (meth)acrylic monomer and the third monofunctional (meth)acrylic monomer may be different from each other.

The mixture may include the first monofunctional (meth)acrylic monomer, the second monofunctional (meth)acrylic monomer, and the third monofunctional (meth)acrylic monomer in a weight ratio of about 10 to 20:2 to 8:1. The mixture may include about 50 parts by weight to about 90 parts by weight, or, for example, about 60 parts by weight to about 80 parts by weight, of the first monofunctional (meth)acrylic monomer, about 5 parts by weight to about 40 parts by weight, or, for example, about 15 parts by weight to about 30 parts by weight, of the second monofunctional (meth)acrylic monomer, and about 0.1 parts by weight to about 10 parts by weight, or, for example, about 1 parts by weight to about 10 parts by weight, of the third monofunctional (meth)acrylic monomer, based on the total weight of the monomer mixture. Within this range, the adhesive film formed of the adhesive composition may secure good bendability.

The first monofunctional (meth)acrylic monomer may include at least one of 2-(2-ethoxyethoxy)ethyl (meth)acrylate, 2-ethylhexyl acrylate, isooctyl acrylate, octadecyl acrylate, lauryl acrylate, and tert-butyl acrylate. The second monofunctional (meth)acrylic monomer may include at least one of hydroxypropyl (meth)acrylate, hydroxybutyl acrylate, and hydroxyethyl methacrylate. The third monofunctional (meth)acrylic monomer may include at least one of isobornyl (meth)acrylate, an aromatic acrylate, and dicyclopentadiene (meth)acrylate.

The monofunctional (meth)acrylic monomer and the polyfunctional (meth)acrylic monomer may be present in a weight ratio of about 1:1 to 5:1, or, for example, about 2:1 to 5:1. Within this range, the adhesive composition may be easily handled and may secure good foldability of the adhesive film.

The monofunctional (meth)acrylic monomer may be present in an amount of about 1 part by weight to about 45 parts by weight, or, for example, about 5 parts by weight to about 35 parts by weight, relative to 100 parts by weight of the (meth)acrylic copolymer, the monofunctional (meth)acrylic monomer and the polyfunctional (meth)acrylic monomer. Within this range, the adhesive composition may achieve a reduction in glass transition temperature of the adhesive film and/or an improvement in adhesive strength thereof.

The polyfunctional (meth)acrylic monomer may provide bendability and good foldability to the adhesive film and, together with the monofunctional (meth)acrylic monomer, may allow a plurality of regions having different moduli to be formed, depending upon the degree of curing of the adhesive film. The polyfunctional (meth)acrylic monomer may increase the modulus of the adhesive layer by increasing the degree of crosslinking of the adhesive layer.

The polyfunctional (meth)acrylic monomer may be a non-urethane based monomer, for example, a polyfunctional (meth)acrylic monomer that is free from a urethane region. The polyfunctional (meth)acrylic monomer may effectively increase the modulus of the adhesive film in the non-bendable region through formation of a dense crosslinking structure. The polyfunctional (meth)acrylic monomer may have a boiling point of about 200° C. or more, for example, of about 200° C. to about 400° C. Within this range, the polyfunctional (meth)acrylic monomer may be prevented from evaporating from the adhesive composition upon removal of a solvent from the adhesive composition by drying. The polyfunctional (meth)acrylic monomer may have a weight average molecular weight of about 800 g/mol to about 2,000 g/mol. Within this range, the polyfunctional (meth)acrylic monomer may suppress phase separation while improving transparency.

The polyfunctional (meth)acrylic monomer may include at least two (meth)acrylate monomers, for example, two to six (meth)acrylate monomers. Examples of the polyfunctional (meth)acrylate may include: bifunctional acrylates such as 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, dicyclopentanyl di(meth)acrylate, caprolactone-modified dicyclopentenyl di(meth)acrylate, ethylene oxide-modified di(meth)acrylate, di(meth)acryloxyethyl isocyanurate, allylated cyclohexyl di(meth)acrylate, tricyclodecane dimethanol (meth)acrylate, dimethylol dicyclopentane di(meth)acrylate, ethylene oxide-modified hexahydrophthalic acid di(meth)acrylate, tricyclodecane dimethanol (meth)acrylate, neopentylglycol-modified trimethylpropane di(meth)acrylate, adamantane di(meth)acrylate, and 9,9-bis[4-(2-acryloyloxyethoxy)phenyl]fluorene; bifunctional acrylates such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, trifunctional urethane (meth)acrylates, tris(meth)acryloxyethylisocyanurate; tetrafunctional acrylates such as diglycerin tetra(meth)acrylate and pentaerythritol tetra(meth)acrylate; pentafunctional acrylates such as dipentaerythritol penta(meth)acrylate; and hexafunctional acrylates such as dipentaerythritol hexa(meth)acrylate and caprolactone-modified dipentaerythritol hexa(meth)acrylate. These may be used alone or in combination thereof. The polyfunctional (meth)acrylic monomer may improve bendability and foldability together with the (meth)acrylic copolymer and the monofunctional (meth)acrylic monomer when cured under predetermined conditions. These may be used alone or in combination thereof. For example, the polyfunctional (meth)acrylic monomer may include a trifunctional acrylate such as trimethylolpropane tri(meth)acrylate. This polyfunctional (meth)acrylic monomer may improve bendability and foldability of the adhesive film after curing of the adhesive film.

The polyfunctional (meth)acrylic monomer may be present in an amount of about 0.1 parts by weight to about 30 parts by weight, or, for example, about 0.5 parts by weight to about 20 parts by weight, relative to 100 parts by weight of the (meth)acrylic copolymer, the monofunctional (meth)acrylic monomer and the polyfunctional (meth)acrylic monomer. Within this range, the polyfunctional (meth)acrylic monomer may increase the modulus of the adhesive film through formation of a dense crosslinking structure.

The initiator may cure the (meth)acrylic copolymer, the monofunctional (meth)acrylic monomer, and the polyfunctional (meth)acrylic monomer. The initiator may include a photopolymerization initiator. The photopolymerization initiator may include, for example, benzoin, hydroxyl ketone, amino ketone, phosphine oxide photoinitiators, or the like. For example, the photopolymerization initiator may include benzoin, benzoin methyl ether, benzoin ethyl ether, benzoin isopropyl ether, benzoin n-butyl ether, benzoin isobutyl ether, an acetophenone compound, such as 2,2-dimethoxy-2-phenylacetophenone, 2,2′-diethoxyacetophenone, 2,2′-dibutoxyacetophenone, 2-hydroxy-2-methylpropiophenone, p-t-butyl tri-chloro-acetophenone, p-t-butyl di-chloro-acetophenone, 4-chloro-acetophenone, 2,2′-dichloro-4-phenoxyacetophenone, dimethylaminoacetophenone, 2,2-dimethoxy-2-phenylacetophenone, 2,2-diethoxy-2-phenylacetophenone, 2-hydroxy-2-methyl-l-phenylpropane-l-one, and 2-benzyl-2-dimethyl amino-1-(4-morpholino phenyl)-butane-1-one, 1-hydroxycyclohexylphenylketone, 2-methyl-1[4-(methylthio)phenyl]-2-morpholino-propane-1-one, 4-(2-hydroxyethoxy)phenyl-2-(hydroxy-2-propyl)ketone, benzophenone, p-phenylbenzophenone, 4,4-bis(diethyl)aminobenzophenone, dichlorobenzophenone, 2-methylanthraquinone, 2-ethylanthraquinone, 2-t-butylanthraquinone, 2-aminoanthraquinone, 2-methylthioxanthone(thioxanthone), 2-ethylthioxanthone, 2-chlorothioxanthone, 2,4-dimethylthioxanthone, 2A-diethylthioxanthone, benzyl dimethyl ketal, acetophenone dimethyl ketal, p-dimethylaminobenzoic acid ester, oligo[2-hydroxy-2-methyl-1-[4-(1-methylvinyl)phenyl]propanone] and 2,4,6-trimethylbenzoyl-diphenyl-phosphine oxide. For example, an acetophenone compound, a benzyl ketal type compound or a mixture thereof is used.

The initiator may be present in an amount of about 0.001 parts by weight to about 5 parts by weight, for example, about 0.005 parts by weight to about 3 parts by weight, relative to 100 parts by weight of the (meth)acrylic copolymer, the monofunctional (meth)acrylic monomer and the polyfunctional (meth)acrylic monomer. Within this range, the adhesive composition may be completely cured, deterioration in transmittance due to a remaining initiator may be prevented, bubble generation may be suppressed, and good reactivity may be exhibited.

The adhesive composition may further include a silane coupling agent. The silane coupling agent may increase adhesion of the adhesive film to an adherend (for example, a glass substrate). The silane coupling agent may be a general silane coupling agent. For example, the silane coupling agent may include at least one selected from the group of epoxy structure-containing silicon compounds such as 3-glycidoxypropyltrimethoxysilane, 3-glycidoxypropyltriethoxysilane, 3-glycidoxypropylmethyl dimethoxysilane, and 2-(3,4-epoxycyclohexyl)ethyltrimethoxysilane; polymerizable unsaturated group-containing silicon compounds such as vinyltrimethoxysilane, vinyltriethoxysilane, and (meth)acryloxypropyltrimethoxysilane; amino group-containing silicon compounds such as 3-aminopropyl trimethoxysilane, N-(2-aminoethyl)-3-aminopropyl trimethoxysilane, and N-(2-aminoethyl)-3-aminopropyl methyl dimethoxysilane; and 3-chloropropyltrimethoxysilane. For example, a silane coupling agent having an epoxy structure may be used.

The silane coupling agent may be present in an amount of about 0.01 parts by weight to about 0.1 parts by weight, or, for example, about 0.05 parts by weight to about 0.1 parts by weight, relative to 100 parts by weight of the (meth)acrylic copolymer, the monofunctional (meth)acrylic monomer and the polyfunctional (meth)acrylic monomer. Within this range, the silane coupling agent may increase reliability of the adhesive film formed of the adhesive composition including the same.

Optionally, the adhesive composition may further include typical additives, such as curing accelerators, ionic liquids, lithium salts, inorganic fillers, softeners, molecular weight regulators, antioxidants, anti-aging agents, stabilizers, adhesion-imparting resins, reforming resins (polyol, phenol, acrylic, polyester, polyolefin, epoxy, epoxidized polybutadiene resins, or the like), leveling agents, defoamers, plasticizers, dyes, pigments (coloring pigments, extender pigments, or the like), processing agents, UV blocking agents, fluorescent whitening agents, dispersants, heat stabilizers, photostabilizers, UV absorbers, antistatic agents, coagulants, lubricants, solvents, or the like.

The adhesive composition may further include a solvent in order to facilitate mixing of the above components while securing coatability of the adhesive composition and good appearance of the adhesive film. The solvent may be or include ethyl acetate, as an example. The adhesive composition may have a viscosity at 25° C. of about 300 cP to about 50.000 cP. Within this range, the adhesive composition may exhibit good coatability and may provide uniform thickness.

An optical member according to an embodiment may include an optical film and an adhesive film or an adhesive layer formed on at least one surface of the optical film. The adhesive film may include an adhesive film according to embodiments. The adhesive layer may be formed using the adhesive film according embodiments. Accordingly, the adhesive layer may have good bendability and foldability. The adhesive layer may include both a bendable region having a lower modulus and a non-bendable region having a higher modulus. Accordingly, the optical member may exhibit good bendability and/or good foldability, and thus may be used in a flexible display. The optical member may also be used in a non-flexible display.

Examples of the optical film may include a polarizing plate, a color filter, a retardation film, an elliptical polarizing film, a reflective film, an anti-reflection film, a compensation film, a brightness improving film, an alignment film, a light diffusion film, a glass shatterproof film, a surface protective film, a plastic LCD substrate, a transparent electrode film such as an indium tin oxide (ITO)-containing film, or the like. For example, a touch panel may be attached to a window film or an optical film via the adhesive film, thereby forming a touch pad. In some implementations, the adhesive film may be applied to a typical polarizing film as in the related art.

The optical member may be produced by forming an adhesive layer through UV irradiation and curing of an adhesive film interposed between two release films, separating the release films from the adhesive layer, and attaching the adhesive layer to the optical film. In some implementations, the optical member may be produced by preparing an adhesive film interposed between two release films, separating the release films from the adhesive film, and attaching the adhesive film to the optical film, followed by UV irradiation. This process may increase the peel strength of the adhesive layer when applied due to low wettability of the adhesive film caused by the high modulus thereof.

An optical display according to an embodiment may include the adhesive film as described herein or an adhesive layer formed of the adhesive film as described herein. The optical display may include an organic light emitting diode (OLED) display, a liquid crystal display, or the like. The optical display may include a flexible display. In some embodiments, the optical display may include a non-flexible display.

Next, a flexible display according to an embodiment will be described with reference to FIG. 3. Referring to FIG. 3, a flexible display 100 may include a display unit 110, an adhesive layer 120, a polarizing plate 130, a touchscreen panel 140, and a flexible window film 150. The adhesive layer 120 may be formed of the adhesive film according to embodiments.

The display unit 110 may drive the flexible display 100. The display unit 110 may include a substrate and an optical device including an OLED, an LED, or an LCD element formed on the substrate. The display unit 110 may include a lower substrate, a thin film transistor, an organic light emitting diode, a planarization layer, a protective layer, and an insulation layer.

The polarizing plate 130 may provide polarization of internal light or prevent the reflection of external light or may increase the contrast of the display. The polarizing plate 130 may be composed of a polarizer alone. In some implementations, the polarizing plate 130 may include a polarizer and a protective film formed on one or both surfaces of the polarizer. In some implementations, the polarizing plate 130 may include a polarizer and a protective coating layer formed on one or both surfaces of the polarizer. As the polarizer, the protective film and the protective coating layer, a general polarizer, a general protective film and a general protective coating layer may be used.

The touchscreen panel 140 may generate electrical signals through the detection of variation in capacitance when a human body or a conductor such as a stylus touches the touchscreen panel 140. The display unit 110 may be driven by such electrical signals. The touchscreen panel 140 may be formed by patterning a flexible conductive conductor. The touchscreen panel 140 may include first sensor electrodes and second sensor electrodes, the second sensor electrodes being formed between the first sensor electrodes and intersecting the first sensor electrodes. The touchscreen panel 140 may include a conductive material such as metal nanowires, conductive polymers, and carbon nanotubes, as examples.

Although FIG. 3 shows a stack structure wherein the polarizing plate 130 and the touchscreen panel 140 are stacked via the adhesive film or a bonding film, the touchscreen panel 140 may be integrally formed with the polarizing plate 130 by encapsulating the polarizer or the polarizing plate in the touchscreen panel 140.

The flexible window film 150 may be formed as an outermost layer of the flexible display 100 to protect the flexible display.

Adhesive layers may be further formed between the polarizing plate 130 and the touchscreen panel 140 and/or between the touchscreen panel 140 and the flexible window film 150 to reinforce bonding between the polarizing plate, the touchscreen panel, and the flexible window film. In addition, a polarizing plate may be further disposed under the display unit 110, thereby providing polarization of internal light

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples

### EXAMPLE

### Preparative Example 1

### Preparation of (meth)acrylic Copolymer

In a 2 [symbol] reactor, a monomer mixture including 364 g of 2-ethylhexyl acrylate and 20 g of 3-hydroxypropyl acrylate was placed. 368 g of ethyl acetate was added to the monomer mixture and the reactor was purged with nitrogen for 1.5 hours. With an inner temperature of the reactor increased to 60° C., a solution (prepared by adding 0.16 g of azobisisobutyronitrile (AIBN) to 32 g of ethyl acetate) was added to the monomer mixture while maintaining the temperature of the monomer mixture. After the inner temperature of the reactor reached 60° C., a reaction was maintained for 15 minutes. The monomer mixture was further subjected to polymerization for 2 hours, and then cooled and diluted with ethyl acetate, thereby preparing an acrylic copolymer solution comprising 18 wt % of an acrylic copolymer in terms of solid content. The prepared acrylic copolymer had a weight average molecular weight of 1,900,000 g/mol.

### Preparative Example 2

### Preparation of (meth)acrylic Copolymer

A (meth)acrylic copolymer (weight average molecular weight: 1,900,000 g/mol) was prepared in the same manner as in Preparative Example 1 except that a monomer mixture including 364 g of 2-ethylhexyl acrylate, 20 g of 3-hydroxypropyl acrylate, 12 g of acrylic acid, and 4 g of poly(ethylene glycol)methylether acrylate (molecular weight: 480) was used.

### Preparative Example 3

### Preparation of Mixture Including Monofunctional (meth)acrylic Monomer and Polyfunctional (meth)acrylic Monomer

A monomer mixture was prepared by mixing (2-ethoxyethoxy)ethyl acrylate (EEEA), 3-hydroxypropyl acrylate (HPA), isobornyl acrylate (IBOA) and trimethylolpropane triacrylate(TMPTA) in a weight ratio of 5.8:2.1:0.4:1.7 (EEEA:HPA:IBOA:TMPTA) based on a total of 10 parts by weight.

### Preparative Example 4

### Preparation of Monofunctional (meth)acrylic Monomer Mixture

A monofunctional acrylic monomer mixture was prepared by mixing (2-ethoxyethoxy)ethyl acrylate (EEEA), 3-hydroxypropyl acrylate (HPA), and isobornyl acrylate (IBOA) in a weight ratio of 7:2.5:0.5 (EEEA:HPA:IBOA) based on a total of 10 parts by weight.

### Example 1

An adhesive composition was prepared by adding a photoinitiator (Irgacure 184) to a mixture prepared by mixing 7 parts by weight of the acrylic copolymer prepared in Preparative Example 1 and 3 parts by weight of the monomer mixture prepared in Preparative Example 3. The photoinitiator was added in an amount of 0.5 wt % to the monomer mixture of Preparative Example 3. The prepared adhesive composition was coated onto a release film and dried at 110° C. for 5 minutes, thereby forming an adhesive layer (thickness: 50 μm).

### Example 2

An adhesive composition was prepared by adding a photoinitiator (Irgacure 184) to a mixture prepared by mixing 9 parts by weight of the acrylic copolymer prepared in Preparative Example 2 and 1 part by weight of the monomer mixture prepared in Preparative Example 3. The photoinitiator was added in an amount of 0.5 wt % to the monomer mixture of Preparative Example 3. The prepared adhesive composition was coated onto a release film and dried at 110° C. for 5 minutes, thereby forming an adhesive layer (thickness: 50 μm).

### Example 3

An adhesive layer was prepared in the same manner as in Example 2 except that 8 parts by weight of the acrylic copolymer prepared in Preparative Example 2 and 2 parts by weight of the monomer mixture prepared in Preparative Example 3 were mixed.

### Example 4

An adhesive layer was prepared in the same manner as in Example 2 except that 7 parts by weight of the acrylic copolymer prepared in Preparative Example 2 and 3 parts by weight of the monomer mixture prepared in Preparative Example 3 were mixed.

### Example 5

An adhesive layer was prepared in the same manner as in Example 2 except that 6 parts by weight of the acrylic copolymer prepared in Preparative Example 2 and 4 parts by weight of the monomer mixture prepared in Preparative Example 3 were mixed.

### Comparative Example 1

An adhesive layer was prepared in the same manner as in Example 2 except that the acrylic copolymer prepared in Preparative Example 2 was used alone.

### Comparative Example 2

An adhesive layer was prepared in the same manner as in Example 2 except that 9 parts by weight of the acrylic copolymer prepared in Preparative Example 2 and 1 part by weight of the monomer mixture prepared in Preparative Example 4 were mixed.

Property Evaluation

The adhesive layers prepared in Examples and Comparative Examples were evaluated as to the following properties and evaluation results are shown in Table 1.

(1) T-peel Strength

A PET film having a size of about 150 mm×about 25 mm×about 75 μm (length×width×thickness) was subjected to corona treatment twice (total dose: 156) under a corona discharge at a dose of 78 using a corona treatment device. An adhesive film having a thickness of 50 μm was formed through irradiation of each of the adhesive layers prepared in Examples and Comparative Examples at an intensity of 800 mW/cm² and a dose of 3,000 mJ/cm², and the release film was removed therefrom. Then, the corona-treated surfaces of the PET films were laminated on both surfaces of the adhesive film having a size of 100 mm×25 mm (length×width), followed by aging at 25° C. for 12 hours, thereby preparing a specimen, as shown in FIG. 2(a). Referring to FIG. 2(b), with the specimen secured to a Universal Testing Machine (Instron), the PET film at one side was kept fixed, and the PET film at the other side was pulled at a rate of 50 mm/min in order to measure T-peel strength upon peeling of the adhesive film. The T-peel strength was measured at 25° C. and 60° C.

(2) Modulus

A 50 μm thick adhesive film was obtained by irradiating each of the adhesive layers prepared in Examples and Comparative Examples with UV light at an intensity 800 mW/cm² and a dose of 3,000 mJ/cm², and the release film was removed from the adhesive film. A specimen having a size of 10 mm×10 mm was prepared by stacking the adhesive film to a thickness of 600 μm. With the specimens attached to both sides of a middle substrate, the viscoelasticity was measured in a shear strain mode under conditions of a frequency of 1 Hz and a strain of 2% (displacement: 16 μm) using a dynamic viscoelasticity instrument DMA (SDTA861, Mettler Co., Ltd.). In the measurement, the temperature was increased from −100° C. to 100° C. at a rate of 5° C./min, and the modulus was measured at −20° C., 25° C., and 80° C.

(3) Glass Transition Temperature

An adhesive film was obtained by irradiating each of the adhesive layers prepared in Examples and Comparative Examples with UV light at an intensity of 800 mW/cm² and a dose of 3,000 mJ/cm². A sample was prepared using 15 mg of the adhesive film (on 6 mm Λl Pan), and the glass transition temperature (Tg) of the adhesive film was measured under a nitrogen atmosphere (50 mL/min). In the measurement of the glass transition temperature, the sample was heated to 180° C. at 20° C./min and cooled to −80° C. (first heating conditions (1st run)), and then heated again to 180° C. at 20° C./min.

(4) Foldability Evaluation:

An adhesive film was obtained by irradiating each of the adhesive layers of Examples and Comparative Examples with UV light at an intensity 800 mW/cm² and a dose of 3,000 mJ/cm². A specimen was obtained by sequentially stacking a corona treated PET film (thickness: 75 μm), the adhesive film (thickness: 75 μm) and a corona treated PET film (thickness: 75 μm), followed by aging at 25° C. for 12 hours. In the evaluation, the specimen was secured to a bendability evaluation instrument (CFT-200, Covotech Co., Ltd.). Folding was performed at a temperature of −20° C. or 25° C. to a radius of curvature of 3 mm or less, thirty times per minute by maintaining the specimen in a folded stated for 0.1 seconds after folding the specimen once. Assuming that 1 cycle refers to an operation of folding the adhesive film in half once and unfolding the adhesive film back in the foldability evaluation, a minimum number of folding cycles at which a striped pattern was initially created at a folded portion of the adhesive film, or fracture, slight lifting or peeling of the adhesive film started to occur was counted. An adhesive film having a minimum number of cycles of 50,000 or more was rated as ο and an adhesive film having a minimum number of cycles of less than 50,000 was rated as ×.

(5) Optical Properties:

A specimen having an adhesive film interposed between 75 μm thick PET films was obtained by curing each of the adhesive layers of Examples and Comparative Examples with UV light at an intensity 800 mW/cm² and a dose of 3,000 mJ/cm². A reference specimen was prepared by stacking two PET films. Optical properties of the specimen were measured using a spectrophotometer (Konica Minolta CM3600d) in transmittance opacity/haze modes. Total light transmittance and haze were measured with respect to the 50 μm thick adhesive film in accordance with ASTM D 1003-95 5 “Standard Test for Haze and Luminous Transmittance of Transparent Plastic”.

(6) Bubble Generation:

A specimen having an adhesive film (thickness: 50 μm) interposed between release films was obtained by curing each of the adhesive layers of Examples and Comparative Examples with UV light at an intensity 800 mW/cm² and a dose of 3,000 mJ/cm². After removal of the release films, the adhesive film was stacked on a glass substrate and an ITO (indium tin oxide) film was stacked on the adhesive film to prepare a specimen having a structure of glass substrate/adhesive layer/ITO film (length×width, 5 cm×5 cm). The specimen was left in a chamber under constant temperature/constant humidity (60° C./93% RH) for 24 hours and evaluated as to bubble generation of the adhesive film. Generation of bubbles was rated by ο and generation of no bubbles was rated by ×.

TABLE 1

| | T-peel | | | | | | Foldability | | Optical | | |
|---|---|---|---|---|---|---|---|---|---|---|---|
| | strength (gf/in) | | Modulus (MPa) | | | Glass | evaluation | | Property (%) | | |
| | @ | @ | @ | @ | @ | transition | @ | @ | Total light | | |
| | 25° C. | 60° C. | 20° C. | 25° C. | 80° C. | temp. (° C.) | 20° C. | 25° C. | transmittance | Haze | Bubbles |
| Example 1 | 1453 | 232 | 0.28 | 0.1 | 0.06 | −42 | ∘ | ∘ | 91.0 | 0.40 | x |
| Example 2 | 726 | 1025 | 0.64 | 0.084 | 0.025 | −36 | ∘ | ∘ | 91.6 | 0.42 | x |
| Example 3 | 859 | 969 | 0.71 | 0.08 | 0.056 | −33 | ∘ | ∘ | 91.1 | 0.42 | x |
| Example 4 | 1016 | 1312 | 1.01 | 0.14 | 0.081 | −32 | ∘ | ∘ | 92.0 | 0.52 | x |
| Example 5 | 1028 | 1197 | 2.56 | 0.25 | 0.120 | −29 | ∘ | ∘ | 91.9 | 0.32 | x |
| Comparative | 1857 | 792 | 0.28 | 0.065 | 0.038 | −36 | ∘ | x | 91.2 | 0.43 | ∘ |
| Example 1 | | | | | | | | | | | |
| Comparative | 310 | 1250 | 0.27 | 0.071 | 0.041 | −34 | ∘ | ∘ | 91.7 | 0.52 | ∘ |
| Example 2 | | | | | | | | | | | |

As shown in Table 1, the adhesive film of Examples exhibited good foldability and high peel strength, and did not suffer from bubble generation.

Conversely, the adhesive film of Comparative Example 1, which did not include the monofunctional (meth)acrylic monomer and the polyfunctional (meth)acrylic monomer, had poor foldability and suffered from bubble generation. The adhesive film of Comparative Example 2, which did not include the polyfunctional (meth)acrylic monomer, had low peel strength at room temperature and suffered from bubble generation.

Adhesive films were produced using the adhesive layers of Examples and Comparative Examples through UV irradiation at 800 mW/cm² while changing the UV dose, as shown in Table 2, and modulus of each of the adhesive films was measured by the same method as above. Here, in \textcircled{1} and \textcircled{2}, modulus of a region of an adhesive film subjected to secondary UV irradiation was measured.

TABLE 2

| | | | | | | | | Comparative | Comparative |
|---|---|---|---|---|---|---|---|---|---|
| UV Irradiation | | | Example 1 | Example 2 | Example 3 | Example 4 | Example 5 | Example 1 | Example 2 |
| Primary | Modulus | @ −20° C. | 0.12 | 0.28 | 0.46 | 0.78 | 1.31 | 0.28 | 0.18 |
| irradiation at | (MPa) | @ 25° C. | 0.047 | 0.065 | 0.074 | 0.11 | 0.17 | 0.065 | 0.061 |
| 200 mJ/cm² | | @ 80° C. | 0.025 | 0.038 | 0.048 | 0.069 | 0.093 | 0.038 | 0.04 |
| Primary | Modulus | @ 20° C. | 0.15 | 0.4 | 0.54 | 0.82 | 1.35 | 0.28 | 0.22 |
| irradiation at | (MPa) | @ 25° C. | 0.066 | 0.072 | 0.08 | 0.13 | 0.18 | 0.065 | 0.062 |
| 400 mJ/cm² | | @ 80° C. | 0.039 | 0.044 | 0.051 | 0.074 | 0.095 | 0.038 | 0.039 |
| \textcircled{1} After | Modulus | @ −20° C. | 0.18 | 0.46 | 0.64 | 0.94 | 2.19 | 0.28 | 0.24 |
| primary | (MPa) | @ 25° C. | 0.084 | 0.077 | 0.078 | 0.13 | 0.20 | 0.065 | 0.067 |
| irradiation at | | @ 80° C. | 0.051 | 0.049 | 0.059 | 0.077 | 0.099 | 0.038 | 0.033 |
| 200 mJ/cm², | | | | | | | | | |
| only part of | | | | | | | | | |
| adhesive film is | | | | | | | | | |
| subjected to | | | | | | | | | |
| secondary | | | | | | | | | |
| irradiation at | | | | | | | | | |
| 600 mJ/cm² | | | | | | | | | |
| \textcircled{2} After | Modulus | @ 20° C. | 0.28 | 0.64 | 0.75 | 1.02 | 2.56 | 0.28 | 0.27 |
| primary | (MPa) | @ 25° C. | 0.1 | 0.084 | 0.08 | 0.14 | 0.25 | 0.065 | 0.071 |
| irradiation at | | @ 80° C. | 0.06 | 0.051 | 0.066 | 0.081 | 0.12 | 0.038 | 0.041 |
| 200 mJ/cm². | | | | | | | | | |
| only part of | | | | | | | | | |
| adhesive film is | | | | | | | | | |
| subjected to | | | | | | | | | |
| secondary | | | | | | | | | |
| irradiation at | | | | | | | | | |
| 3,000 mJ/cm² | | | | | | | | | |

As shown in Table 2, the adhesive composition according to embodiments allowed easy adjustment of modulus through suitable adjustment of the irradiation dose. Conversely, the adhesive composition composed of the copolymer alone as in Comparative Example 1 did not permit a modulus change and the adhesive composition formed of the copolymer and the monofunctional monomer as in Comparative Example 2 did not provide a high modulus due to difficulty in formation of a dense crosslinking structure.

By way of summation and review, it is desirable for various optical members included in a flexible display to have flexibility. When a transparent adhesive layer is interposed between the window film and the conductive film, it is desirable for the transparent adhesive layer to have good adhesive strength at both surfaces thereof. In addition, it is desirable for the transparent adhesive layer to have good bendability and good foldability. For example, the flexible display may include a bendable region in which bending occurs and a non-bendable region in which bending may not occur. Generally, the bendable region will be a portion at which the flexible display will be folded by a user. The non-bendable region may be located around the bendable region and may be a portion at which a user will hold the flexible display. It is desirable for the flexible display to exhibit good bendability and good foldability in the bendable region. In addition, it is desirable for the flexible display to prevent depression of the transparent adhesive layer, and fracture and/or deformation of an organic light emitting diode panel in the non-bendable region.

The embodiments provide an adhesive film having good foldability both at room temperatures and at low temperatures. Embodiments provide an adhesive film having high peel strength both at room temperature and high temperature. Embodiments provide an adhesive film having good reliability at high temperature. Embodiments provide an adhesive film exhibiting optical transparency due to no phase separation between components in the adhesive film. Embodiments provide an adhesive film that is composed of a single layer and includes a plurality of regions having different moduli, thereby securing good bendability while preventing depression of the adhesive film, and fracture and/or deformation of an organic light emitting diode panel when used in a display.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An adhesive film having a glass transition temperature of about −10° C. or lower, the adhesive film including a first region and a second region, the second region being coplanar with the first region, wherein:
the second region has a higher modulus than the first region at about −20° C.,
the first region has a modulus of about 0.01 MPa to about 1.5 MPa at about −20° C., and
the second region has a modulus of about 0.1 MPa to about 50 MPa at about −20° C.

2. The adhesive film as claimed in claim 1, wherein the adhesive film has a modulus of about 0.05 MPa to about 5 MPa at about −20° C. and a modulus of about 0.01 MPa to about 1 MPa at about 80° C.

3. The adhesive film as claimed in claim 1, wherein the adhesive film has a peel strength ratio of about 1.1 or more, as calculated by Equation 1:
Peel strength ratio=B/A, [Equation 1]
wherein A is peel strength of the adhesive film at 25° C. and B is peel strength of the adhesive film at 60° C.

4. The adhesive film as claimed in claim 1, wherein the adhesive film is formed from an adhesive composition including a (meth)acrylic copolymer, a monofunctional (meth)acrylic monomer, a polyfunctional (meth)acrylic monomer, and an initiator.

5. The adhesive film as claimed in claim 4, wherein each of the monofunctional (meth)acrylic monomer and the polyfunctional (meth)acrylic monomer has a boiling point of about 200° C. or more.

6. The adhesive film as claimed in claim 4, wherein each of the monofunctional (meth)acrylic monomer and the polyfunctional (meth)acrylic monomer is a non-urethane based (meth)acrylic monomer.

7. The adhesive film as claimed in claim 4, wherein the monofunctional (meth)acrylic monomer includes at least one of isobornyl (meth)acrylate, 2-ethylhexyl (meth)acrylate, isooctyl (meth)acrylate, lauryl (meth)acrylate, hydroxypropyl (meth)acrylate, hydroxyethyl (meth)acrylate, stearyl (meth)acrylate, 3-trimethoxysilylpropyl (meth)acrylate, diacetone (meth)acrylamide, (meth)acrylamide, 2-(2-ethoxyethoxy)ethyl (meth)acrylate, 2-methoxyethyl (meth)acrylate, tetrahydrofurfuryl (meth)acrylate, ethylene glycolphenylether(meth)acrylate, isodecyl (meth)acrylate, 2-((meth)acryloyloxy)ethyl succinate, isostearyl(meth)acrylate, caprolactone (meth)acrylate, N,N-dimethyl (meth)acrylamide, octyl (meth)acrylate, octadecyl (meth)acrylate, t-butyl (meth)acrylate, hydroxybutyl (meth)acrylate, di cyclopentadiene (meth)acrylate, and an aromatic acrylate.

8. The adhesive film as claimed in claim 4, wherein the monofunctional (meth)acrylic monomer is a mixture including a first monofunctional (meth)acrylic monomer, a second monofunctional (meth)acrylic monomer, and a third monofunctional (meth)acrylic monomer in a weight ratio of about 10 to 20:2 to 8:1.

9. The adhesive film as claimed in claim 8, wherein:
the first monofunctional (meth)acrylic monomer is at least one of 2-(2-ethoxyethoxy)ethyl (meth)acrylate, 2-ethylhexyl acrylate, isooctyl acrylate, octadecyl acrylate, lauryl acrylate, and t-butyl acrylate;
the second monofunctional (meth)acrylic monomer is at least one of hydroxypropyl (meth)acrylate, hydroxybutyl acrylate, and hydroxyethyl methacrylate; and
the third monofunctional (meth)acrylic monomer is at least one of isobornyl (meth)acrylate, dicyclopentadiene (meth)acrylate, and an aromatic acrylate.

10. The adhesive film as claimed in claim 4, wherein the polyfunctional (meth)acrylic monomer includes two to six (meth)acrylate groups.

11. The adhesive film as claimed in claim 4, wherein the monofunctional (meth)acrylic monomer and the polyfunctional (meth)acrylic monomer are present in a weight ratio of about 1:1 to 5:1.

12. The adhesive film as claimed in claim 4, wherein the (meth)acrylic copolymer is a copolymer of a hydroxyl group-containing (meth)acrylic monomer and an alkyl group-containing (meth)acrylic monomer.

13. The adhesive film as claimed in claim 4, wherein the (meth)acrylic copolymer is a copolymer of a hydroxyl group-containing (meth)acrylic monomer, an alkyl group-containing (meth)acrylic monomer, an ethylene glycol unit-containing (meth)acrylate, and a carboxylic acid group-containing monomer.

14. The adhesive film as claimed in claim 1, wherein the adhesive film has a peel strength at 25° C. of about 500 gf/in or more with respect to a polyethylene terephthalate film subjected to corona treatment.

15. The adhesive film as claimed in claim 1, wherein the adhesive film has a haze of about 1% or less in the visible region.

16. The adhesive film as claimed in claim I wherein the adhesive film has a total light transmittance of about 90% or more in the visible region.

17. The adhesive film as claimed in claim 1, wherein the adhesive film has a number of folding cycles of 50,000 or more at about −20° C. and a radius of curvature of about 5 mm or less.

18. The adhesive film as claimed in claim 1, wherein a difference in modulus at about −20° C. between the first region and the second region is about 0.05 MPa or more.

19. An optical member comprising an optical film and an adhesive film formed on the optical film, wherein the adhesive film includes the adhesive film as claimed in claim 1.

20. An optical display comprising the adhesive film as claimed in claim 1.
